(19) United States
(12) Patent Application Publication
(10) Pub. No.: US 2017/0213951 A1
(43) Pub. Date: Jul. 27, 2017

(54) FLEXIBLE THIN MULTI-LAYERED THERMOELECTRIC ENERGY GENERATING MODULE, VOLTAGE BOOSTING MODULE USING SUPER CAPACITOR, AND PORTABLE THERMOELECTRIC CHARGING APPARATUS USING THE SAME

(71) Applicant: KOREA RESEARCH INSTITUTE OF STANDARDS AND SCIENCE, Daejeon (KR)

(72) Inventors: YONG-GYOO KIM, Daejeon (KR); SU YONG KWON, Daejeon (KR); JAEYONG SONG, Daejeon (KR)

(21) Appl. No.: 15/217,380

(22) Filed: Jul. 22, 2016

(30) Foreign Application Priority Data
Jan. 27, 2016 (KR) 10-2016-0009979
May 11, 2016 (KR) 10-2016-0057542

(51) Int. Cl. H01L 35/32; H02J 7/00; H01L 35/10

(52) U.S. Cl. CPC H01L 35/32; H01L 35/10; H02J 7/0072; H02J 7/345

(57) ABSTRACT

The present disclosure provides a flexible thin multi-layered thermoelectric energy generating module in which a unit thermoelectric sheet having an optimized number of contacts and p/n junctions is formed on a single plane, a voltage boosting module using a super capacitor, and a portable thermoelectric charging apparatus using the same. Herein, the unit thermoelectric sheet having an optimized number of contacts has a shape, a thickness, and a width which exhibits best performance at a given temperature difference. To this end, an aspect of the present disclosure includes a thermoelectric energy generating module which converts thermal energy into electric energy; a voltage boosting module which is electrically connected to the thermoelectric energy generating module to boost a voltage of the electric energy; an output unit which is electrically connected to the voltage boosting module to output the electric energy whose voltage is boosted by the voltage boosting module; and a control unit.

### CROSS-REFERENCE TO RELATED APPLICATIONS

This application claims the priority of Korean Patent Application No. 2016-0009979 filed on Jan. 27, 2016 and No. Korean Patent Application No. 2016-0057542 filed on May 11, 2016, in the Korean Intellectual Property Office, the disclosure of which is incorporated herein by reference.

### BACKGROUND

Field

The present disclosure relates to a flexible thin multi-layered thermoelectric energy generating module, a voltage boosting module using a super capacitor, and a portable thermoelectric charging apparatus using the same. More particularly, the present disclosure relates to a device for thermoelectric generation in which planar thermoelectric modules are three-dimensionally laminated on a thin flexible substrate to increase an amount of power to be generated for a unit plane, a flexible thin multi-layered thermoelectric energy generating module which provides a three-dimensional thermoelectric energy generating module by laminating unit modules in series or in parallel to select in accordance with a utilizing purpose whether to amplify a voltage or a current, a voltage boosting module using a super capacitor including a plurality of capacitors, and a thermoelectric charging apparatus including the same in which a thermoelectric element which converts thermal energy into electric energy is deposited on a flexible substrate to improve portability.

Description of the Related Art

Generally, in the related art, a heat engine converts thermal energy into kinetic energy and then converts the kinetic energy into electric energy using a generator. According to the thermoelectric generation, thermal energy is directly converted into electric energy using a thermoelectric effect.

In a planar thermoelectric charging apparatus of the related art, in order to achieve a high output, a circuit is configured on a single plain to form a plurality of p/n junctions. However, in this case, resistance of an element is increased, which decreases a generated current. Therefore, the output is correspondingly lowered.

In order to overcome the above-mentioned drawback, a method, which increases a cross-section of an electrode to reduce the resistance, has been suggested. However, according to this method, a number of useful p/n junctions are reduced in a limited space, so that the output is also lowered.

In the related art, not only electric and electronic products, but also vehicles use an electric cell as a power source to drive or operate equipment. Therefore, equipment using the electric cells has various functions so that power consumption is increased. The increased power consumption results in an increased capacity of the battery.

In the battery of the related art, the battery mounted in the equipment is used as a main power source and thus an entire battery capacity depends on the capacity of the battery. Therefore, in order to increase the capacity of the battery, a volume of the battery should be increased, so that downsizing of a product such as a portable terminal is restricted.

Specifically, smart phones have become very popular in recent years and a consumed energy amount of the smart phone is much larger than that of a feature phone. Therefore, a battery of the smart phone needs to be frequently exchanged or frequently charged.

In order to solve the above-described problem, as illustrated in FIG. 1A, an auxiliary battery is used to charge to a portable terminal such as a smart phone. However, the volume of the auxiliary battery is large and the auxiliary battery needs to be charged separately so that it is not convenient to use the auxiliary battery.

Further, as illustrated in FIG. 1B, a device which includes a generating unit using solar heat or sunlight to charge the portable terminal, has been developed. However, the volume of the device is so large that it is not convenient to carry the device.

Further, the above-described thermoelectric charging apparatus cannot output a voltage enough to charge the portable terminal.

Therefore, it is required to develop a voltage-boosting module, which boosts a voltage enough to charge the portable terminal and a portable charging apparatus including the same.

### SUMMARY

The present disclosure has been made in an effort to provide a flexible thin multi-layered thermoelectric energy generating module having an optimized number of contacts in which a unit thermoelectric sheet having an optimized number of contacts and p/n junctions is formed on a single plane and has a shape, a thickness, and a width which exhibits best performance at a given temperature difference is formed, a voltage boosting module using a super capacitor, and a portable thermoelectric charging apparatus using the same.

The present disclosure provides a flexible thin multi-layered thermoelectric energy generating module which is capable of manufacturing a thermoelectric module in which unit thermoelectric sheets formed on a thin flexible substrate, is three-dimensionally laminated to configure an integrated module to amplify a desired level of output generated for a predetermined area to have a sufficient energy generation capacity, a voltage boosting module using a super capacitor, and a portable thermoelectric charging apparatus using the same.

The present disclosure provides a flexible thin multi-layered thermoelectric energy generating module in which unit thermoelectric sheets are connected in series or in parallel to freely select whether to amplify a voltage or a current, a voltage boosting module using a super capacitor, and a portable thermoelectric charging apparatus using the same.

Further, the present disclosure provides a flexible thin multi-layered thermoelectric energy generating module, a voltage boosting module using a super capacitor, and a portable thermoelectric charging apparatus using the same to a user.

Specifically, the present disclosure avoids inconvenience of frequently charging and exchanging the battery.

Further, when it is necessary to use portable electronic equipment in an area where the battery cannot be charged or suddenly use the portable electronic equipment, power is supplied to the portable electronic equipment.

Further, a charging apparatus, which has a good portability to be inserted in a wallet, a portable phone case, or a belt, is provided to the user.

Further, an electrode change-over switch is used to charge the battery using not only a heat source, but also a cooling source.

Further, a voltage of electric energy output from the thermoelectric charging apparatus is increased to supply a voltage enough to charge the portable terminal.

According to a first exemplary embodiment of the present disclosure, there is provided a flexible thin multi-layered thermoelectric energy generating module. The flexible thin multi-layered thermoelectric energy generating module is a thermoelectric energy generating device in which a multi-layered unit thermoelectric sheet is formed, a p-type semiconductor element and an n-type semiconductor element are formed in the unit thermoelectric sheet, and the p-type semiconductor element and the n-type semiconductor element are coupled in the same horizontal and vertical direction to form a p/n semiconductor with an electric parallel circuit configuration. Herein, in the unit thermoelectric sheet, a thermoelectric semiconductor unit in which a plurality of p-type semiconductor elements and a plurality of n-type semiconductor elements are alternately formed, a contact unit in which the thermoelectric semiconductor unit forms an electric contact to generate thermoelectric phenomenon, and an electrode unit which is connected to the thermoelectric semiconductor unit to move electric energy formed in the contact unit and converted into a positive electrode and a negative electrode to transfer the energy to the outside are formed.

A via hole may be formed in the electrode unit to be configured in the positive electrode and the negative electrode with the same shape.

The electrode unit may be formed on a top layer of the unit thermoelectric sheet.

According to a second exemplary embodiment of the present disclosure, there is provided a flexible thin multi-layered thermoelectric energy generating module. The flexible thin multi-layered thermoelectric energy generating module is a thermoelectric energy generating device in which a multi-layered unit thermoelectric sheet is formed, a p-type semiconductor element and an n-type semiconductor element are formed in the unit thermoelectric sheet, and the p-type semiconductor element and the n-type semiconductor element intersect in horizontal and vertical directions to form a p/n semiconductor with an electric series circuit configuration. Herein, in the unit thermoelectric sheet, a thermoelectric semiconductor unit in which a plurality of p-type semiconductor elements and a plurality of n-type semiconductor elements are alternately formed, a contact unit in which the thermoelectric semiconductor unit forms an electric contact to generate thermoelectric phenomenon, and an electrode unit which is connected to the thermoelectric semiconductor unit to move electric energy formed in the contact unit and converted into a positive electrode and a negative electrode to transfer the energy to the outside are formed.

On each layer of the unit thermoelectric sheet, via holes may be alternately formed in a positive electrode and a negative electrode.

Anyone of the positive electrode and the negative electrode of the electrode unit may be formed on a top layer or a bottom layer of the unit thermoelectric sheet.

The unit thermoelectric sheet may be formed by a polymer-based substrate, which is flexible and curved, such as a polyimide film or a PDMS film.

The contact units may be stepwisely formed to be coupled to each other.

An exemplary embodiment of the present disclosure provides a voltage-boosting module, which boosts an output voltage of a thermoelectric charging apparatus. The voltage boosting module includes a voltage input unit which receives an output voltage of the thermoelectric charging apparatus; a plurality of capacitors which is connected to the voltage input unit in parallel and is connected to each other in series; a voltage output unit which is connected to both ends of the plurality of capacitors connected in series to output a voltage which is applied to the plurality of capacitors; a plurality of input switch sets including a first switch which controls a current between one end of each of the plurality of capacitors and one end of the voltage input unit and a second switch which controls a current between the other end of each of the plurality of capacitors and the other end of the voltage input unit; a plurality of third switches which controls a current between a node to which the first switch is connected and a node to which the second switch is connected between the plurality of capacitors; a fourth switch, which controls the current between the node to which the first switch, is connected and one end of the voltage output unit, between both ends of the plurality of capacitors; and a control unit which controls operations of the plurality of input switch sets, the plurality of third switches, and the fourth switch. Herein, the control unit turns on at least one of the plurality of input switch sets and turns off the plurality of third switches and the fourth switch to control an output voltage of the thermoelectric charging apparatus to be applied to at least one of the plurality of capacitors, and turns off the plurality of input switch sets and turns on the plurality of third switches and the fourth switch to control a voltage which is applied to the plurality of capacitors to be applied to the voltage output unit.

The voltage-boosting module may further include a power measuring sensor which measures electric power applied to the plurality of capacitors; and a display unit which outputs the electric power.

An exemplary embodiment of the present disclosure provides a flexible thin multi-layered thermoelectric energy generating module, a voltage-boosting module using a super capacitor, and a portable thermoelectric charging apparatus using the same. The portable thermoelectric charging apparatus includes a thermoelectric energy generating module which converts thermal energy into electric energy; a voltage boosting module which is electrically connected to the thermoelectric energy generating module to boost a voltage of the electric energy; an output unit which is electrically connected to the voltage boosting module to output the electric energy whose voltage is boosted by the voltage boosting module; and a control unit. The thermoelectric energy generating module includes a first substrate on which a plurality of first thermoelectric members is deposited and a second substrate on which a plurality of second thermoelectric members is deposited, the first thermoelectric members and the second thermoelectric members form thermocouples, the first substrate and the second substrate are welded such that a surface on which the plurality of first thermoelectric members is deposited and a surface on which the plurality of second thermoelectric members is deposited are in contact with each other. The plurality of first thermoelectric members is deposited in a direction from one end of the first substrate toward the other end and the plurality of second thermoelectric members is deposited in a direction from one end of the second substrate toward the other end. The plurality of first thermoelectric members and the plurality of second thermoelectric members are alternately connected in series and one end of an n-th thermoelectric member of the plurality of first thermoelectric members and the other end of an n+1-th thermoelectric member are connected by the second thermoelectric member. The voltage-boosting module may be electrically connected to one end and the other end of the first thermoelectric member and the second thermoelectric member, which are connected in series; the first substrate and the second substrate may be flexible substrates. The voltage boosting module includes a voltage input unit which receives the electric energy; a plurality of capacitors which is connected to the voltage input unit in parallel and is connected to each other in series; a voltage output unit which is connected to both ends of the plurality of capacitors connected in series to output electric energy with a voltage, which is applied to the plurality of capacitors, to the output unit; a plurality of input switch sets including a first switch which controls a current between one end of each of the plurality of capacitors and one end of the voltage input unit and a second switch which controls a current between the other end of each of the plurality of capacitors and the other end of the voltage input unit; a plurality of third switches which controls a current between a node to which the first switch is connected and a node to which the second switch is connected, respectively, between the plurality of capacitors; and a fourth switch which controls the current between the node to which the first switch is connected between both ends of the plurality of capacitors and one end of the voltage output unit. The control unit turns on at least one of the plurality of input switch sets and turns off the plurality of third switches and the fourth switch to control an output voltage of the thermoelectric energy generating module to be applied to at least one of the plurality of capacitors, and turns off the plurality of input switch sets and turns on the plurality of third switches and the fourth switch to control a voltage which is applied to the plurality of capacitors to be applied to the voltage output unit.

The portable thermoelectric charging apparatus may further include an electrode change-over switch, which changes a polarity of the electric energy output from the output unit into an opposite polarity.

The thermoelectric charging apparatus may further include a storage battery, which is electrically connected to the voltage-boosting module to store the electric energy. Herein, the output unit is electrically connected to the storage battery to output the stored electric energy.

The voltage of the electric energy, which is converted by the thermoelectric energy generating module, may be determined by the following Equation.

E(V)=(T₁−T₂)×S×n [Equation]

(in Equation, E(V) is a voltage of the electric energy, T₁ is a temperature at a point where one end of the plurality of first thermoelectric members and one end of the plurality of second thermoelectric members are in contact with each other, T₂ is a temperature at a point where the other end of the plurality of first thermoelectric members and the other end of the plurality of second thermoelectric members are in contact with each other, S is a Seebeck coefficient of the thermocouple formed by the first thermoelectric member and the second thermoelectric member, and n is the number of thermocouples formed by the plurality of first and second thermoelectric members.)

The portable thermoelectric charging apparatus may further include a power measuring sensor which measures electric power applied to the plurality of capacitors; and a display unit which outputs the electric power.

According to the flexible thin multi-layered thermoelectric energy generating module, a voltage boosting module using a super capacitor, and a portable thermoelectric charging apparatus using the same of the present disclosure, as compared with a single layer thermoelectric energy generating module, high generation power per unit area may be obtained.

According to the flexible thin multi-layered thermoelectric energy generating module, a voltage boosting module using a super capacitor, and a portable thermoelectric charging apparatus using the same of the present disclosure, when a serial connection structure is employed, high voltage output is obtained and when a parallel connection structure is employed, high current output is obtained.

Further, according to the flexible thin multi-layered thermoelectric energy generating module, a voltage-boosting module using a super capacitor, and a portable thermoelectric charging apparatus using the same of the present disclosure, the contact units are stepwisely laminated so that effective thermal contact with respect to an ambient environment may be obtained.

The present disclosure provides a portable thermoelectric charging apparatus and a manufacturing method thereof to a user.

Specifically, the present disclosure reduces inconvenience of frequently charging and exchanging the battery.

Further, when it is necessary to use portable electronic equipment in an area where the battery cannot be charged or suddenly use the portable electronic equipment, power is supplied to the portable electronic equipment.

Further, a charging apparatus, which has a good portability to be inserted in a wallet, a portable phone case, or a belt, may be provided to the user.

Further, an electrode change-over switch is used to charge the battery using not only a heat source, but also a cooling source.

Further, a voltage of electric energy output from the thermoelectric charging apparatus is boosted to supply a voltage enough to charge the portable terminal.

The effects of the present disclosure are not limited to aforementioned effects and other effects, which are not mentioned above, will be apparently understood by those skilled in the art from the following description.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1A illustrates an auxiliary battery, which charges a portable terminal;

FIG. 1B illustrates a photovoltaic energy generating charger, which charges a portable terminal;

FIG. 2 is an exploded perspective view of a flexible thin multi-layered thermoelectric energy generating module according to a first exemplary embodiment of the present disclosure;

FIG. 2A is a cross-sectional view of the flexible thin multi-layered thermoelectric energy generating module taken along the line A-A of FIG. 1;

FIG. 2B is a cross-sectional view of the flexible thin multi-layered thermoelectric energy generating module taken along the line B-B of FIG. 1;

FIG. 2C is a cross-sectional view of the flexible thin multi-layered thermoelectric energy generating module taken along the line C-C of FIG. 1;

FIG. 3 is an exploded perspective view of a flexible thin multi-layered thermoelectric energy generating module according to a second exemplary embodiment of the present disclosure;

FIG. 3A is a cross-sectional view of the flexible thin multi-layered thermoelectric energy generating module taken along the line A-A of FIG. 2;

FIG. 3B is a cross-sectional view of the flexible thin multi-layered thermoelectric energy generating module taken along the line B-B of FIG. 2;

FIG. 3C is a cross-sectional view of the flexible thin multi-layered thermoelectric energy generating module taken along the line C-C of FIG. 2;

FIG. 4 is a view illustrating that two types of metals, which generate a Seebeck effect are connected;

FIG. 5 is a block diagram of a thermoelectric charging apparatus according to an exemplary embodiment of the present disclosure;

FIG. 6A is a view illustrating one surface of a first substrate according to an exemplary embodiment of the present disclosure;

FIG. 6B is a view illustrating one surface of a second substrate according to an exemplary embodiment of the present disclosure;

FIG. 6C is a view illustrating a structure in which a first thermoelectric member and a second thermoelectric member according to an exemplary embodiment of the present disclosure are connected to each other;

FIG. 7 is a cross-sectional view illustrating that a first substrate and a second substrate are welded together according to an exemplary embodiment of the present disclosure;

FIGS. 8A to 8C are views illustrating a structure in which a first substrate and a second substrate, a first thermoelectric member and a second thermoelectric member according to an exemplary embodiment of the present disclosure are connected to each other;

FIG. 9 is a plan view of a thermoelectric charging apparatus including an electrode change-over switch according to an exemplary embodiment of the present disclosure;

FIG. 10 is a view illustrating an example of changing an electrode of an electrode change-over switch according to an exemplary embodiment of the present disclosure;

FIG. 11 illustrates that a portable terminal is directly connected to a thermoelectric charging apparatus according to an exemplary embodiment of the present disclosure;

FIG. 12 illustrates that an extending line is connected to a thermoelectric charging apparatus according to an exemplary embodiment of the present disclosure and an application is implemented in a portable terminal, which is connected to an end of the extending line;

FIG. 13 is a circuit diagram of a voltage-boosting module according to an exemplary embodiment of the present disclosure;

FIG. 14 is a circuit diagram illustrating that electric energy is applied to a plurality of capacitors according to an exemplary embodiment of the present disclosure; and

FIG. 15 is a circuit diagram illustrating that the electric energy, which is applied to a plurality of capacitors according to an exemplary embodiment of the present disclosure, is applied to a voltage output unit.

### DETAILED DESCRIPTION OF THE EMBODIMENT

Hereinafter, a configuration and an operation of an exemplary embodiment of the present disclosure will be described in detail with reference to the accompanying drawings. Here, like reference numerals denote like components and redundant description will be omitted.

### 1. Flexible Thin Multi-Layered Thermoelectric Energy Generating Module According to First Exemplary Embodiment

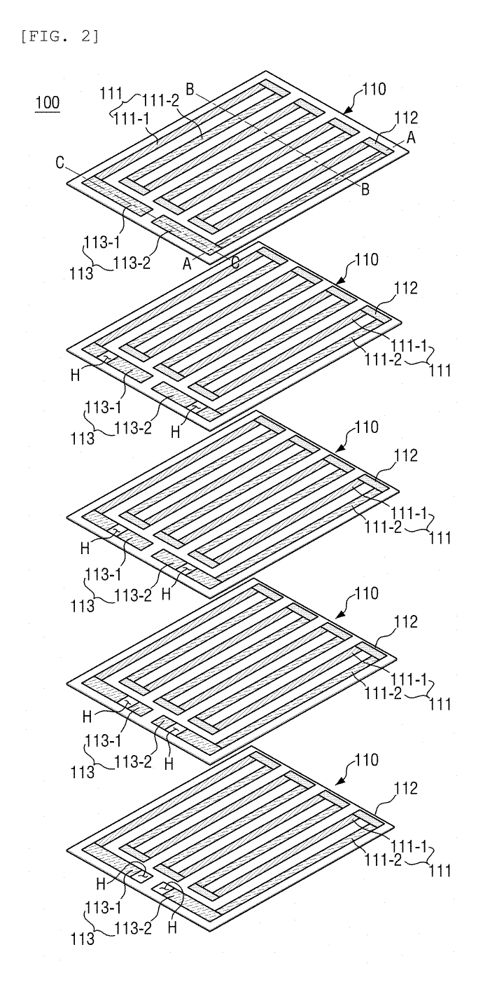

FIG. 2 is an exploded perspective view of a flexible thin multi-layered thermoelectric energy generating module according to a first exemplary embodiment of the present disclosure, in which

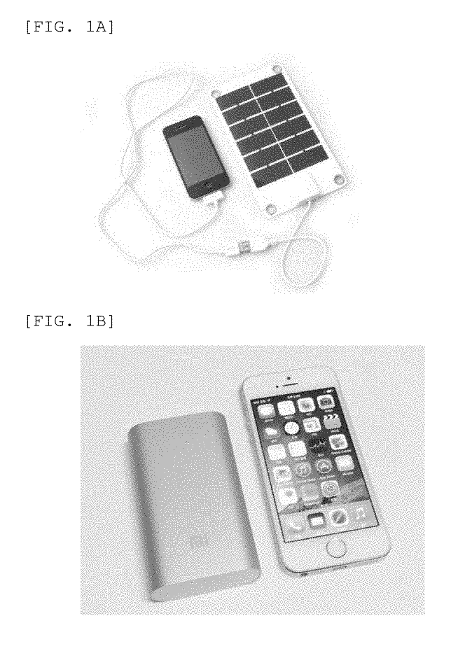

FIG. 2A is a cross-sectional view of the flexible thin multi-layered thermoelectric energy generating module taken along the line A-A of FIG. 1;

FIG. 2B is a cross-sectional view of the flexible thin multi-layered thermoelectric energy generating module taken along the line B-B of FIG. 1; and

FIG. 2C is a cross-sectional view of the flexible thin multi-layered thermoelectric energy generating module taken along the line C-C of FIG. 1;

### 1. (1) Configuration of Flexible Thin Multi-Layered Thermoelectric Energy Generating Module

As illustrated in the drawings, a flexible thin multi-layered thermoelectric energy generating module 100, is formed by a multi-layered unit thermoelectric sheet 110 formed on a thin flexible substrate. In the unit thermoelectric sheet 110, a p-type semiconductor element 111-1 and an n-type semiconductor element 111-2 are formed. Further, the p-type semiconductor element 111-1 and the n-type semiconductor element 111-2 are coupled in the same horizontal and vertical directions to form a p/n semiconductor.

In the unit thermoelectric sheet 110, a thermoelectric semiconductor unit 111, a contact unit 112, and an electrode unit 113.

In the thermoelectric semiconductor unit 111, a plurality of p-type semiconductor elements 111-1 and a plurality of n-type semiconductor elements 111-2 are alternately formed so that thermal energy is collected.

A multi-layered thermoelectric semiconductor unit 111 is formed. The p-type semiconductor element 111-1 and the n-type semiconductor element 111-2 which are formed on each layer are disposed with a constant interval and are coupled to each other in a co-axial position.

The contact units 112 are stepwisely laminated to be coupled to each other and an electric conductive paste is applied to couple the contact units 112.

The electrode unit 113 is formed on a top layer among the layers of the unit thermoelectric sheet 110. The electrode unit 113 is connected to the thermoelectric semiconductor unit 111 to be converted into a positive electrode 113-1 and a negative electrode 113-2 to transfer energy to the outside.

Further, in the unit thermoelectric sheet 110, via holes H are formed in the positive electrode 113-1 and the negative electrode 113-2 to be configured with the same shape. No component is inserted into the via holes H. The via holes H are formed for electric connection between different layers.

The paste applied in the via hole H is formed to serve as an electric conductor between thermoelectric sheets.

The flexible thin multi-layered thermoelectric energy generating module 100 according to the present disclosure may further include an insulating layer (not illustrated).

### 1. (2) Effect of Flexible Thin Multi-Layered Thermoelectric Energy Generating Module

The flexible thin multi-layered thermoelectric energy generating module according to the first exemplary embodiment configured as described above has a structure in which unit thermoelectric sheets 110 are laminated. As compared with a general unit thermoelectric sheet having a single layer structure, a higher energy generation output per unit area may be obtained.

Further, the flexible thin multi-layered thermoelectric energy generating module 100 according to the first exemplary embodiment has a parallel structure. As compared with the general unit thermoelectric sheet having a single layer structure, a higher current output may be obtained.

Further, the voltage may be calculated by the following Equation.

V≡ΔT·S·N·m

(Here, ΔT is a temperature difference, S is a Seebeck coefficient, N is the number of unit thermoelectric sheets, and m is the number of contacts of each unit thermoelectric sheet)

As m is increased, that is, the number of contact units 112 is increased, the resistance is also increased. In order to avoid increasing the resistance, N is increased. Further, in order to maximize thermal contact with the outside, the contact units are stepwisely laminated to maximize an area of the contact units 112, which is exposed to an external heat source.

The flexible thin multi-layered thermoelectric energy generating module 100 formed as described above may amplify the current so that it is suitable to charge a battery for a wearable device.

### 2. Flexible Thin Multi-Layered Thermoelectric Energy Generating Module According to Second Exemplary Embodiment

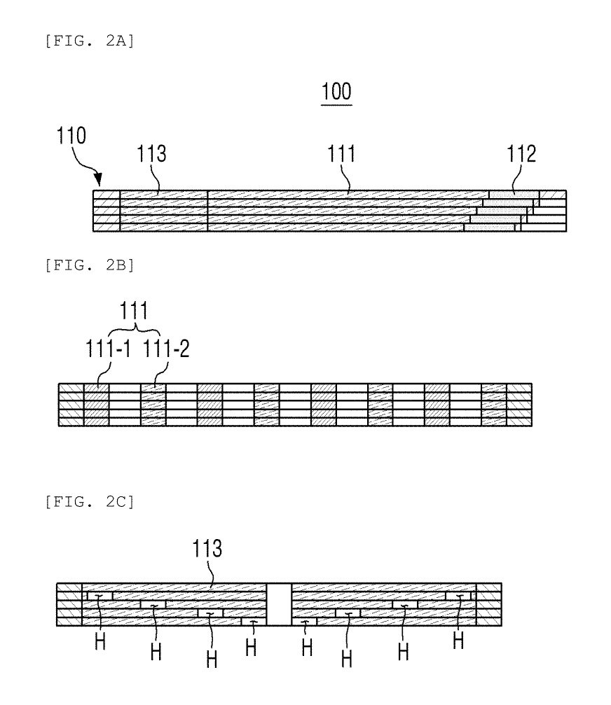

FIG. 3 is an exploded perspective view of a flexible thin multi-layered thermoelectric energy generating module according to a second exemplary embodiment of the present disclosure.

FIG. 3A is a cross-sectional view of the flexible thin multi-layered thermoelectric energy generating module taken along the line A-A of FIG. 2.

FIG. 3B is a cross-sectional view of the flexible thin multi-layered thermoelectric energy generating module taken along the line B-B of FIG. 2.

FIG. 3C is a cross-sectional view of the flexible thin multi-layered thermoelectric energy generating module taken along the line C-C of FIG. 2;

### 2. (1) Configuration of Flexible Thin Multi-Layered Thermoelectric Energy Generating Module

As illustrated in the drawings, a flexible thin multi-layered thermoelectric energy generating module 100′ is formed by a multi-layered unit thermoelectric sheet 110′ formed on a thin flexible substrate. In the unit thermoelectric sheet 110′, a p-type semiconductor element 111-1′ and an n-type semiconductor element 111-2′ are formed. Further, the p-type semiconductor element 111-1′ and the n-type semiconductor element 111-2′ are coupled to horizontally and vertically intersect each other to form a p/n semiconductor.

In the unit thermoelectric sheet 110′, a thermoelectric semiconductor unit 111′ in which a plurality of p-type semiconductor elements 111-1′ and a plurality of n-type semiconductor elements 111-2′ are alternately arranged to generate thermal energy, a contact unit 112′ which transfers the thermal energy generated in the thermoelectric semiconductor unit 111′ to an upper layer or a lower layer, and an electrode unit 113′ which is connected to the thermoelectric semiconductor unit 111′ to be converted into a positive electrode 113-1′ and a negative electrode 113-2′ to transfer energy to the outside are formed.

When the flexible thin multi-layered thermoelectric energy generating module 100′ according to the second exemplary embodiment of the present disclosure is compared with the flexible thin multi-layered thermoelectric energy generating module 100 according to the first exemplary embodiment of the present disclosure, only structures in which the p-type semiconductor elements 111-1 and 111-1′ and the n-type semiconductor elements 111-2 and 111-2′ are coupled, positions where the electrode units 113 and 113′ are formed, and positions and shapes of the via holes H are different from each other.

More specifically, a technical configuration, a shape, and an organic connection have been described with reference to FIGS. 1 and 1A to 1C, so that detailed description of the flexible thin multi-layered thermoelectric energy generating module 100′ according to the second exemplary embodiment of the present disclosure will be omitted.

### 2. (2) Effect of Flexible Thin Multi-Layered Thermoelectric Energy Generating Module

The flexible thin multi-layered thermoelectric energy generating module according to the second exemplary embodiment configured as described above has a structure in which unit thermoelectric sheets 110 are laminated. As compared with the unit thermoelectric sheet having a single layer structure, higher energy generation output per unit area may be obtained.

Further, in the flexible thin multi-layered thermoelectric energy generating module 100′ according to the second exemplary embodiment, the thermoelectric semiconductor unit 110′ has a serial structure. As compared with the general unit thermoelectric sheet having a single layer structure, a higher voltage output may be obtained.

Similarly to the flexible thin multi-layered thermoelectric energy generating module 100 according to the first exemplary embodiment of the present disclosure, the voltage of the flexible thin multi-layered thermoelectric energy generating module 100′ according to the second exemplary embodiment of the present disclosure will be calculated by the following Equation.

V≡ΔT·S·m

(Here, ΔT is a temperature difference, S is a Seebeck coefficient, and m is the number of contacts)

As m is increased, that is, the number of contact units 112′ is increased, the resistance is also increased and a generated current is reduced. In order to compensate this, the contact units 112′ are stepwisely laminated to maximize the generated voltage. Therefore, the contact unit 112′ maybe applied to a field in which a voltage is mainly required, rather than a current.

The flexible thin multi-layered thermoelectric energy generating module 100′ formed as described above may amplify the voltage.

### 3. Thermoelectric Charging Apparatus

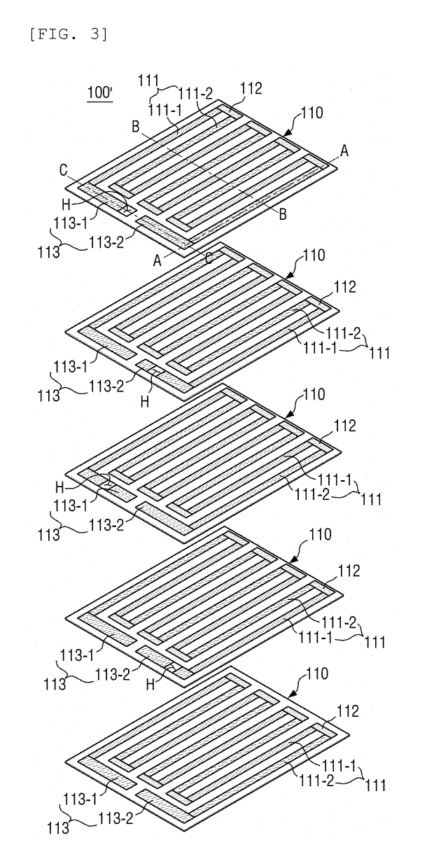

FIG. 4 is a view illustrating that two types of metals, which generate a Seebeck effect are connected. As illustrated in FIG. 4, when both ends of two different metals or semiconductors are bonded and a temperature difference is applied thereto, electromotive force is generated in a circuit, which is called Seebeck effect. This phenomenon was discovered for Cu and Bi or Sb by T. Seebeck in 1821.

A thermocouple thermometer which measures thermoelectromotive force and converts the thermoelectromotive force into a temperature using the Seebeck effect is widely used in industries and various thermocouples from a high temperature to a very low temperature have been developed.

There are various thermocouples for temperature measurement, such as silver-gold (iron is added), chromel-gold (iron is added), copper-constantan, chromel-constantan, chromel-alumel, platinum.rhodium-platinum, or tungsten-tungsten-rhenium.

In the meantime, a thermoelectric power (Seebeck coefficient) of the semiconductor is much higher than that of a metal. Therefore, a thermoelectric generator using the semiconductor has been developed to be used for an unmanned observatory in a polar region, a lighthouse, or a power source for a beacon of the ocean floor.

The Seebeck effect will be described in more detail below.

For more understanding, the Seebeck effect is a phenomenon in which the electromotive force is generated by a temperature difference of two different metal junctions. A pair of thermoelectric elements which are different metals generating the Seebeck effect is called thermocouples.

A material, which is the most widely used as the thermoelectric element, is Bi₂Te₃ and Sb₂Te₃ based materials.

A voltage generated by the Seebeck effect may be represented by the following Equation 1.

$$α = \frac{Δ V}{Δ T} [ μ V / K ] \qquad [ Equation 1 ]$$

Here, α is a value referred to as a Seebeck coefficient and indicates a voltage induced from a unit temperature difference. Generally, a Seebeck coefficient of a metal is very small, for example, several tens of μtV/K and a Seebeck coefficient of a semiconductor alloy is several hundreds of μV/K. As the value of the Seebeck coefficient is increased, the electromotive force generated by the thermoelectric effect is increased. Therefore, a material with a high Seebeck coefficient may be a good thermoelectric element.

In the meantime, in the field of the thermoelectric element, a ZT value is used as a figure of merit for judging a characteristic of a thermoelectric element of each material. For example, when there is a temperature difference in which a temperature of a low temperature part is T_{L} and a temperature of a high temperature part is T_{H}, a thermal conductivity of a material used for the thermoelectric effect is k, and an electric conductivity is σ, ZT is represented by the following Equation 2.

$$ZT = \frac{{α}^{2} σ T}{k} \qquad [ Equation 2 ]$$

Here, T indicates an average temperature of the high temperature part and the low temperature part, that is, T=(T_{H}+T_{L})/2.

In Equation 2, ZT is proportional to a square of the Seebeck coefficient. Therefore, it can be understood that when the value of ZT is high, a high thermoelectric effect is obtained. Silicon which is a widely used semiconductor material has an electric conductivity of 150 W/cm²K and the ZT at the room temperature is just 0.01.

Therefore, when an n-type semiconductor material and a p-type semiconductor material are used and temperatures are different at both ends, a carrier in the semiconductors moves to generate the electromotive force. The electromotive force is used to simply generate electricity.

In the meantime, the electromotive force (thermoelectromotive force) generated by the Seebeck effect is proportional to a temperature difference between two contacts. A level of the thermoelectric current varies depending on the type of metals or semiconductors, which form a couple (thermocouple) and a temperature difference at two contacts. Further, an electric resistance of a metal wire also involves thereto.

As an example of a metal, which is generally known, in a circuit, which is formed of copper and constantan, when a temperature difference of two contacts is 100° C., an electromotive force of 4.24 mV is generated. Further, the current flows from constantan having a high thermoelectric current to copper having a low thermoelectric current through a contact of the high temperature part.

Hereinafter, an exemplary embodiment of a charging apparatus which generates energy by itself using the Seebeck effect which has been described above with reference to the drawings, that is, the thermoelectric effect, to supply electric energy to a portable terminal will be described.

However, the exemplary embodiment, which will be described below does not unreasonably limit the contents of the present disclosure disclosed in the claims. Further, the entire configuration described in this exemplary embodiment is not necessarily required as the solving means of the present disclosure.

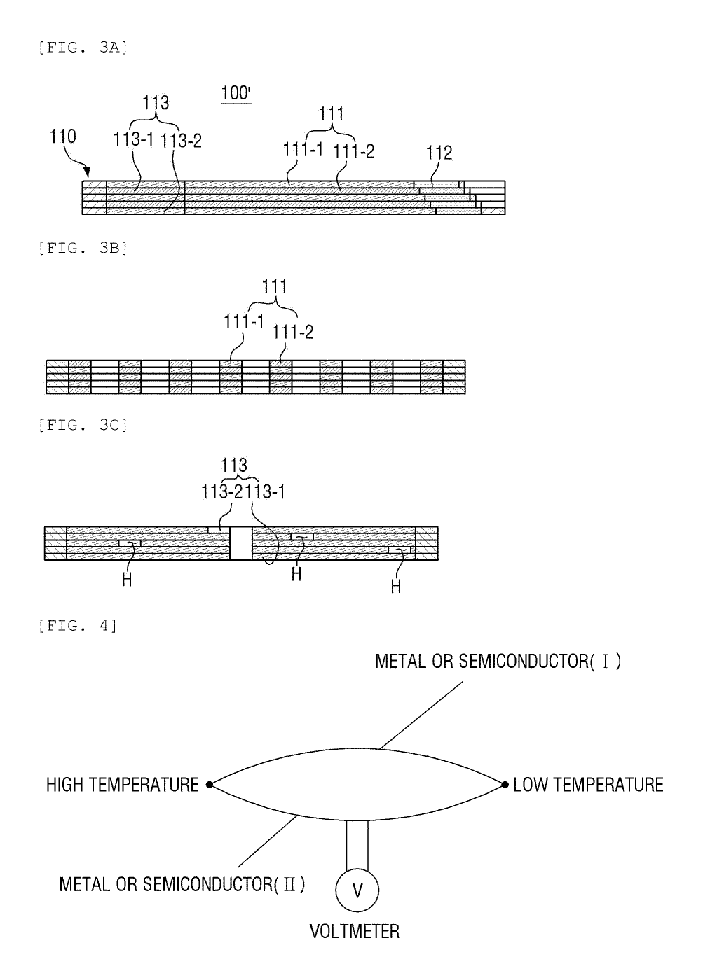

FIG. 5 is a block diagram of a thermoelectric charging apparatus according to an embodiment of the present disclosure.

Referring to FIG. 5, the thermoelectric charging apparatus of the present disclosure includes a thermoelectric energy generating module 100, an output unit 200, an electrode change-over switch 200, a storage battery 400, a voltage-boosting module 500, and a control unit 600. However, the components illustrated in FIG. 5 are not essential components so that a thermoelectric charging apparatus having more components or less components may be implemented.

First, the thermoelectric energy generating module 100 is a configuration, which converts thermal energy into electric energy using the above-described Seebeck effect. The thermoelectric energy generating module 100 may include a first substrate 120a, a first thermoelectric member 120a, a connection line 140, a second substrate 120b, and a second thermoelectric member 130b.

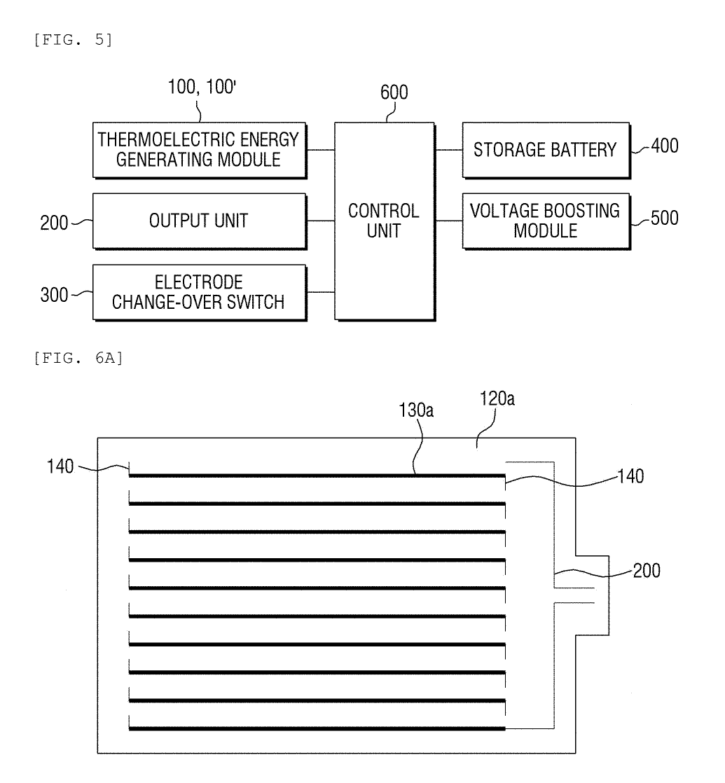

FIG. 6A is a view illustrating one surface of a first substrate according to an exemplary embodiment of the present disclosure. Referring to FIG. 6A, on the first substrate 120a, a plurality of first thermoelectric members 130a is deposited in a direction from one end of the first substrate 120a to the other end. Further, the connection line 140 which connects the first thermoelectric member 130a with the second thermoelectric member 130b, which will be described below may be deposited on the first substrate 120a. Further, the output unit 200, which outputs electric energy generated by the thermoelectric energy generating module 100 may be disposed.

The first substrate 120a may be a flexible substrate using polyimide for portability. Further, the first thermoelectric member 130a is an element, which uses various effects caused by interaction of heat and electricity.

FIG. 6B is a view illustrating one surface of a second substrate according to an exemplary embodiment of the present disclosure. Referring to FIG. 6B, similarly to the first substrate 120a, a plurality of second thermoelectric members 130b is deposited in a direction from one end of the second substrate 120b to the other end. The second thermoelectric member 130b is a thermoelectric element, which forms a thermocouple together with the first thermoelectric member 130a. An example of a thermocouple formed by the first thermoelectric member 130a and the second thermoelectric member 130b is a copper-constantan thermocouple or Bi₂Te₃—Sb₂Te_{3.}

The above-described first substrates 120a and second substrate 120b are welded such that the surfaces on which the plurality of first thermoelectric members 130a and the plurality of thermoelectric members 130b are deposited are in contact with each other.

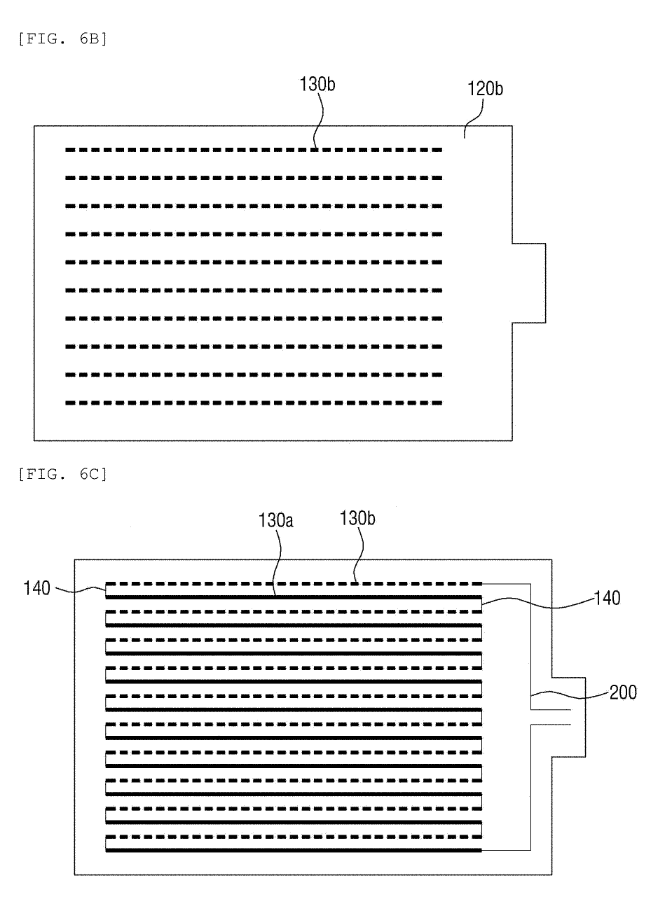

FIG. 7 is a cross-sectional view illustrating that a first substrate and a second substrate are welded together according to an exemplary embodiment of the present disclosure. As illustrated in FIG. 7, the first substrate 120a and the second substrate 120b are welded such that the first thermoelectric members 130a and the second thermoelectric members 130b are connected to each other.

In the meantime, FIG. 6C is a view illustrating a structure in which a first thermoelectric member and a second thermoelectric member according to an exemplary embodiment of the present disclosure are connected to each other.

When the first substrate 120a and the second substrate 120b are welded, the plurality of thermoelectric members 130a and the plurality of thermoelectric members 130b are alternately connected in series. One end of an n-th thermoelectric member and the other end of an n+1-th thermoelectric member, among the plurality of first thermoelectric members 130a, are connected by the second thermoelectric member 130b. In this case, the connection line 140 deposited on the first substrate 120a connects the first thermoelectric members 130a and the second thermoelectric members 130b.

The first thermoelectric members 130a and the second thermoelectric members 130b are alternately connected in series to form a thermocouple. As described above, when the plurality of first thermoelectric members 130a and the plurality of second thermoelectric members 130b are alternately connected in series, an output voltage may be increased. This is because when the plurality of power sources is connected in series, a total voltage is a sum of voltages of individual power sources. A voltage output from the thermoelectric energy generating module 100 is represented by the following Equation 3.

E(V)=(T₁−T₂)×S×n [Equation 3]

(in Equation 3, E (V) is a voltage of the electric energy, T₁ is a temperature at a point where one ends of the plurality of first thermoelectric members 130a and one ends of the plurality of second thermoelectric members 130b are in contact with each other, T₂ is a temperature at a point where the other ends of the plurality of first thermoelectric members 130a and the other ends of the plurality of second thermoelectric members 130b are in contact with each other, S is a Seebeck coefficient of the thermocouple formed by the first thermoelectric member 130a and the second thermoelectric member 130b, and n is the number of thermocouples formed by the plurality of first and second thermoelectric members 130a and 130b.

As represented in Equation 3, as the number of thermocouples formed by the first thermoelectric members 130a and the second thermoelectric members 130b is increased, the output voltage is increased. Further, as the temperature difference between T₁ and T₂ is increased, the output voltage becomes higher.

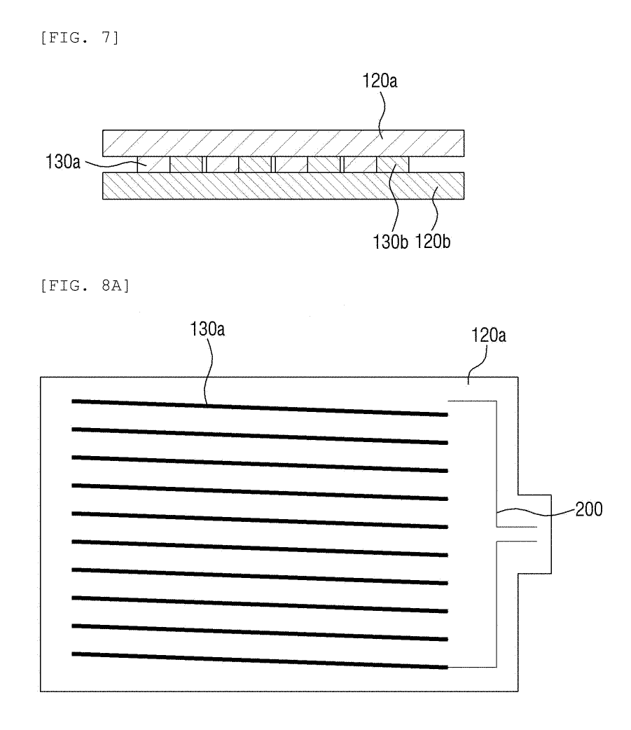

In the meantime, FIGS. 8A to 8C are views illustrating a structure in which the first substrate 120a and the second substrate 120b, the first thermoelectric members 130a and the second thermoelectric members 130b according to an exemplary embodiment of the present disclosure are connected to each other.

FIGS. 8A to 8C illustrate a different exemplary embodiment from that of FIGS. 6A to 6C. When the first substrate 120a and the second substrate 120b are welded, the first thermoelectric members 130a and the second thermoelectric members 130b may be deposited such that the plurality of first thermoelectric members 130a and the plurality of second thermoelectric members 130b are connected to form a zigzag pattern. When the plurality of first thermoelectric members 130a and the plurality of second thermoelectric members 130b are disposed as described above, the first thermoelectric members 130a and the second thermoelectric members 130b may be connected to each other without using the connection line 140 of FIG. 6A.

In the meantime, the thermoelectric energy generating module 100 may be formed to have a size of a name card or a size enough to be inserted in a waist belt or a portable phone case.

For example, the thermoelectric energy generating module 100 may be manufactured to have a quadrangular shape with a horizontal length of 8.6 cm and a vertical length of 5.35 cm, which is an ISO standard of a credit card to be accommodated in a card section of a wallet. That is, the first substrate 120a and the second substrate 120b have a quadrangular shape and a horizontal length of 8.6 cm and a vertical length of 5.35 cm. Further, as a quadrangular shape, which is a standard of a name card, the horizontal length is 8.6 cm and the vertical length is 5.2 cm. Furthermore, as a quadrangular shape, which is a standard of a name card, the horizontal length may be 9 cm and the vertical length may be 5 cm.

Further, in order to attach the thermoelectric energy generating module 100 into the belt, a clip may be added onto one surface to increase portability.

In the meantime, the thermoelectric energy generating module 100 may be soaked in hot water to absorb heat. Therefore, a waterproof process maybe performed on the thermoelectric energy generating module 100 so that water may not permeate therein.

Next, the output unit 200 is a configuration, which is located at one side of the thermoelectric energy generating module 100 and is electrically connected to the thermoelectric energy generating module 100 to output electric energy generated by the thermoelectric energy generating module 100.

Referring to FIGS. 6A and 6B, the output unit 200 is located at one side of the thermoelectric energy generating module 100. Referring to FIG. 6C, the output unit 200 is electrically connected to both ends of the first thermoelectric member 130a and the second thermoelectric member 130b connected in series.

Ends of the output unit 200 may be formed in accordance with a universal serial bus (USB) standard for the sake of a wide use. In order to simply and directly use the output unit 200, the ends of the output unit 200 may be formed by a terminal such as a micro USB, a mini USB (mini 5 pin) or a lightning 8 pin.

Next, the electrode change-over switch 300 is a configuration, which changes a polarity of the electric energy output from the output unit 200 into an opposite polarity.

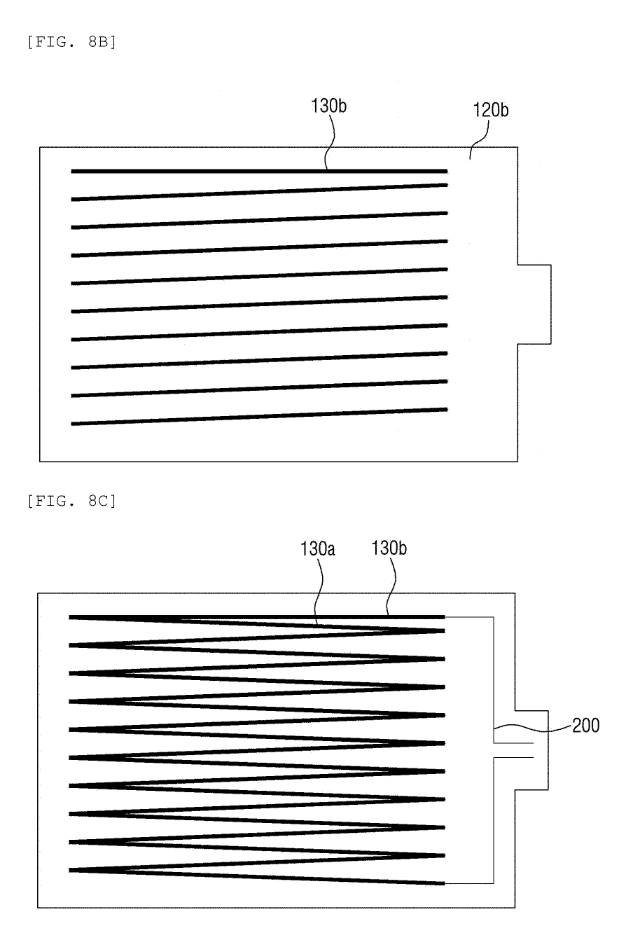

FIG. 9 is a plan view of a thermoelectric charging apparatus including an electrode change-over switch 300 according to an exemplary embodiment of the present disclosure. Referring to FIG. 9, the electrode change-over switch 300 may be disposed on one surface of the thermoelectric energy generating module 100.

When the thermoelectric charging apparatus according to the present disclosure is used, one end of the thermoelectric energy generating module 100 where one of two points where the first thermoelectric member 130a and the second thermoelectric member 130b are in contact with each other is located, that is, a hot contact is in contact with a hand or a body heat of a human or hot water to cause the temperature difference between both ends of the thermoelectric energy generating module 100.

However, when there is no hot heat source which may heat the hot contact or the hand or the body which serves as a heat source is too cold to sufficiently heat the hot contact, the electrode change-over switch 300 is used to change the hot contact into a cold contact and changes the cold contact into the hot contact to generate electricity.

That is, in Equation 3, when it is assumed that T₁ is a temperature of the hot contact of the thermoelectric energy generating module 100 and T₂ is a temperature of the cold contact of the thermoelectric energy generating module 100 which is opposite to the hot contact, if the hot contact is heated so that T₁ is higher than T₂, a positive voltage is generated.

However, in a circumstance where it is hard to heat the hot contact, if the hot contact is in contact with a cold material such as ice water, T₁ is lower than T₂. In this case, when the electrode change-over switch 300 is used to switch the electrode, a positive voltage may be generated.

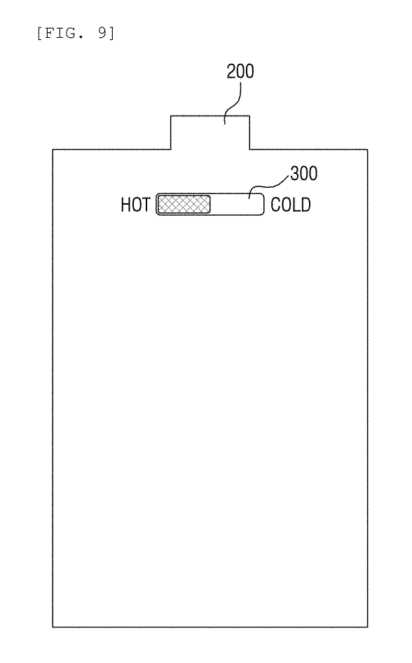

FIG. 10 is a view illustrating an example of changing an electrode of an electrode change-over switch according to an exemplary embodiment of the present disclosure. Referring to FIG. 10, the electrode change-over switch 300 is located in HOT and the electric energy generated in the thermoelectric energy generating module 100 is output to the output unit 200 along a line represented by a solid line. In this case, when the electrode change-over switch 300 is switched to COLD, the electric energy generated in the thermoelectric energy generating module 100 is output to the output unit 200 along a line represented by a dotted line. The hot contact is changed to the cold contact and the cold contact is in contact with a cold point such as ice water to generate the electric energy.

Next, the storage battery 400 is a configuration, which stores the electric energy generated by the thermoelectric energy generating module 100 that is a battery. When the storage battery 400 is equipped, the output unit 200 is also connected to the storage battery 400 to output the electric energy stored in the storage battery 400.

The storage battery 400 may be a thin film cell type.

A material of a thin film base material equipped in the thin film cell may be one selected from a group consisting of polyolefin, a styrenic block copolymer, metallocene-catalyzed polyolefins, polyesters, polyurethanes, and polyether amides or a combination thereof.

When the storage battery 400 is equipped, the thermoelectric charging apparatus may further include a charging circuit unit, which is electrically connected to the thermoelectric energy generating module 100. The storage battery 400 is charged by generating the charging voltage based on the electromotive force generated from the thermoelectric energy generating module 100.

Further, the thermoelectric charging apparatus may further include a detecting unit, which measures a charged amount of the storage battery 400 at real time.

Since the storage battery 400 is equipped, the electric energy is stored in advance. Therefore, when the electric energy cannot be generated using the thermoelectric energy generating module 100, the portable terminal may be charged.

Next, the voltage-boosting module 500 is a configuration, which increases a voltage of the electric energy output from the thermoelectric energy generating module 100. A level of the voltage output when the temperature difference between the hot contact and the cold contact is not sufficient maybe lower than a required level of the voltage. In this case, the voltage-boosting module 500 is used to increase a voltage output from the output unit 200 to charge the portable terminal.

In contrast, the voltage output from the thermoelectric energy generating module 100 maybe higher than the required voltage. Therefore, the thermoelectric charging apparatus may further include a voltage-reducing module, which may reduce the voltage. Further, the thermoelectric charging apparatus may further include a constant voltage module to maintain the voltage to be constant.

Next, the control unit 600 is a configuration, which controls a general operation of individual configurations of the thermoelectric energy generating apparatus of the present disclosure.

Hereinafter, a configuration, which may be additionally included in the thermoelectric charging apparatus of the present disclosure and a portable terminal, which is connected to the thermoelectric charging apparatus of the present disclosure will be described.

The thermoelectric charging apparatus of the present disclosure may further include an extension line 700, which extends an end of the output unit 200, for the convenience of usage.

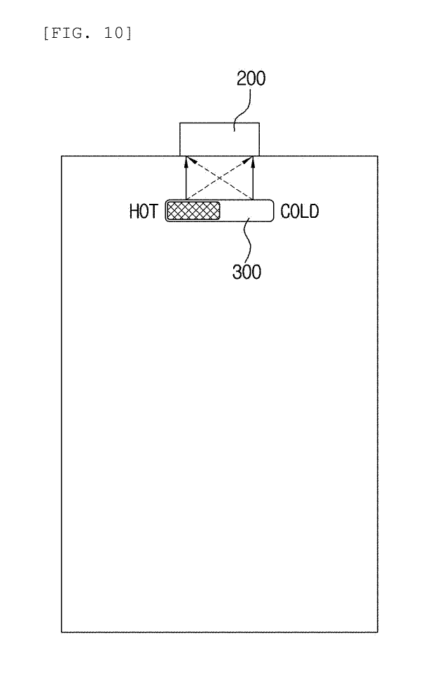

FIG. 11 illustrates that a portable terminal is directly connected to a thermoelectric charging apparatus according to an exemplary embodiment of the present disclosure.

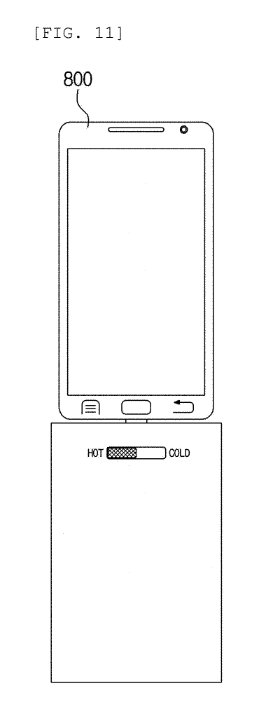

Further, FIG. 12 illustrates that an extending line is connected to a thermoelectric charging apparatus according to an exemplary embodiment of the present disclosure and an application is implemented in a portable terminal, which is connected to an end of the extending line.

As illustrated in FIG. 11, an output terminal of the thermoelectric charging apparatus may be formed of a micro-USB, a mini-USB, a lightning 8 pin so as to be directly engaged with a power input unit of the portable terminal.

Further, as illustrated in FIG. 12, an extension line 700 with a predetermined length is equipped in the output unit 200 of the thermoelectric charging apparatus and the portable terminal 800 is connected to the end of the extension line to be charged. An end of the extension line 700 may be formed in accordance with a universal serial bus (USB) standard for the purpose of generality. In order to simply use the extension line 700, the end may be formed by a terminal such as a micro USB, a mini USB (mini 5 pin) or a lightning 8 pin.

In the meantime, the portable terminal, which is connected with the thermoelectric charging apparatus, may further include a voltage-boosting module, which boosts the voltage of the electric energy supplied from the thermoelectric charging apparatus. The control unit 600 of the portable terminal detects the voltage of the input electric energy. When the detected voltage is lower than a required voltage, the control unit 600 may control the voltage-boosting module to boost the input voltage to be the required voltage.

As illustrated in FIG. 12, the portable terminal, which is connected to the thermoelectric charging apparatus, may include an application, which receives an input of the user to control an operation of the voltage-boosting module. As illustrated in FIG. 12, the portable terminal may detect and display the voltage to be input and receive a voltage, which will be boosted by the voltage-boosting module. However, the application, which controls the voltage-boosting module, is not limited to an example illustrated in FIG. 12.

In the meantime, the thermoelectric charging apparatus of the present disclosure uses a flexible substrate and has a small size, so that the thermoelectric charging apparatus is good to be easily carried or moved. Therefore, an advertising slogan or picture is printed on a surface of the thermoelectric charging apparatus to be utilized as a sales hook, a gift, or a promotional material.

Further, the thermoelectric charging apparatus of the present disclosure may be manufactured in accordance with the ISO standard of a credit card as described above. Therefore, the thermoelectric charging apparatus is coupled to a credit card, a transportation card, or a check card to be used as a credit card equipped with the thermoelectric charging apparatus. This is possible because the thickness of the thermoelectric charging apparatus of the present disclosure is very thin.

Further, the thermoelectric charging apparatus of the present disclosure may be utilized for military supplies, which use the electric energy. For example, when the electric energy of the battery is entirely consumed while carrying out military operations, the thermoelectric charging apparatus of the present disclosure is used to charge the electric energy.

In the meantime, even though the plurality of thermoelectric members is used for the thermoelectric charging apparatus, when the temperature difference between both ends of the thermoelectric member is not so high, it is hard to generate the electric energy having a voltage enough to charge the portable terminal.

That is, as described above, a level of the voltage output when the temperature difference between the hot contact and the cold contact is not sufficient may be lower than a required level of the voltage. In this case, the voltage-boosting module 500 is used to increase a voltage output from the output unit 200 to charge the portable terminal.

Hereinafter, a voltage-boosting module, which boosts the level of the voltage, using a super capacitor will be described with reference to the drawings.

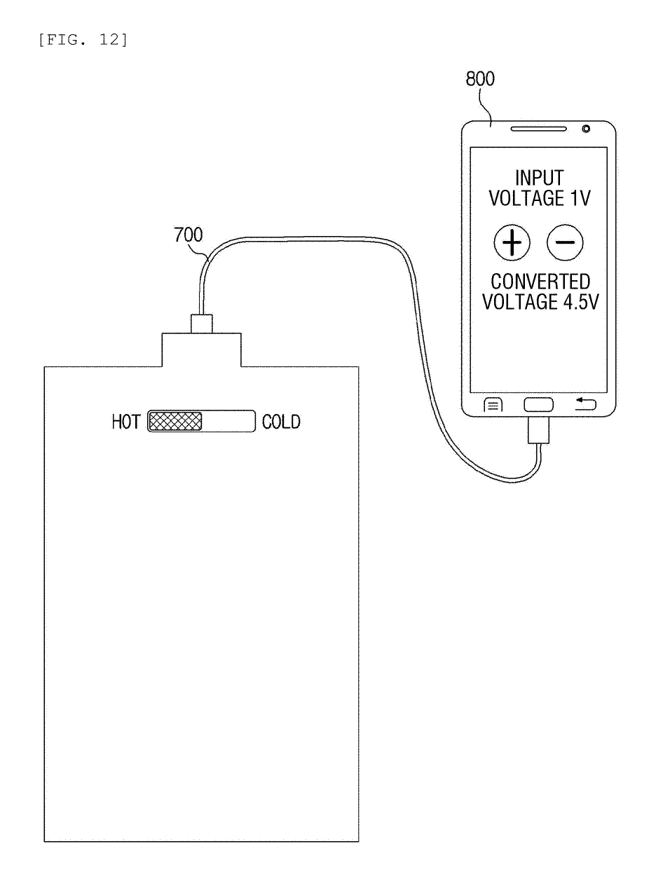

FIG. 13 is a circuit diagram of a voltage-boosting module according to an exemplary embodiment of the present disclosure.

A voltage boosting module of the present disclosure includes a voltage input unit 510, a plurality of capacitors 520, a voltage output unit 530, a plurality of first switches 541, a plurality of second switches 542, a plurality of third switches 543, a fourth switch 544, a plurality of fifth switches 545, a sixth switch 546, a voltage measuring unit 550, a power measuring sensor 560, a display unit 570, and a control unit 600.

First, the voltage input unit 510 is a configuration, which receives an output voltage of the thermoelectric charging apparatus.

The voltage input unit 510 is electrically connected to an output unit of the thermoelectric charging apparatus or is mounted in the thermoelectric charging apparatus to be electrically connected to the thermoelectric energy generating module 100 of the thermoelectric charging apparatus.

Next, the plurality of capacitors 520 is connected to the voltage input unit 510 in parallel and the individual capacitors 520 are connected to each other in series.

The plurality of capacitors 520 forms a super capacitor. The plurality of capacitors is applied with the electric energy from the voltage input unit 510 through the parallel connection and stores the electric energy and applies the stored electric energy to the voltage output unit 530 through the serial connection.

Next, the voltage output unit 530 is connected to both ends of the plurality of capacitors 520, which is connected in series to be applied with the electric energy, which is applied to the plurality of capacitors 520 and transfers the electric energy to the portable terminal.

Next, the plurality of first switches 541 and the plurality of second switches 542 are switches, which configure a input switch set.

As illustrated in FIG. 13, the plurality of first switches 541 controls a current between an end of each of the plurality of capacitors 520 and an end of the voltage input unit 510. The plurality of second switches 542 controls a current between the other end of each of the plurality of capacitors 520 and the other end of the voltage input unit 510.

The first switches 541 and the second switches 542, which form the input switch set, are controlled by the control unit 600. When each of the input switch sets is turned on, the electric energy is applied to the plurality of capacitors 520 from the voltage input unit 510.

Next, the plurality of third switches 543 controls a current between a node to which the first switch 541 is connected and a node to which the second switch 542 is connected, respectively, between the plurality of capacitors 520. The fourth switch 544 controls a current between a node to which the first switch 541 is connected between both ends of the plurality of capacitors 520 and one end of the voltage output unit 530.

That is, when the plurality of third switches 543 and the fourth switch 544 are turned on, the plurality of capacitors 520 are all connected in series. Therefore, the voltages of the electric energy stored in each of the plurality of capacitors 520 are added to be applied to the voltage output unit 530.

Next, the voltage-measuring unit 550 is a configuration, which measures the level of the voltage of the electric energy generated in the thermoelectric charging apparatus or the thermoelectric energy generating module 100.

Next, the power-measuring sensor 560 is a sensor, which measures the electric power stored in the plurality of capacitors 520. The display unit 570 is a configuration, which outputs the electric power measured by the power-measuring sensor 560.

Next, the control unit 600 is a configuration, which controls operations of the plurality of input switch sets, the plurality of third switches 543, and the fourth switch 544.

At least one of the plurality of input switch sets is turned on and the plurality of third switches and the fourth switch 544 are turned off to apply the output voltage of the thermoelectric charging apparatus to at least one of the plurality of capacitors 520.

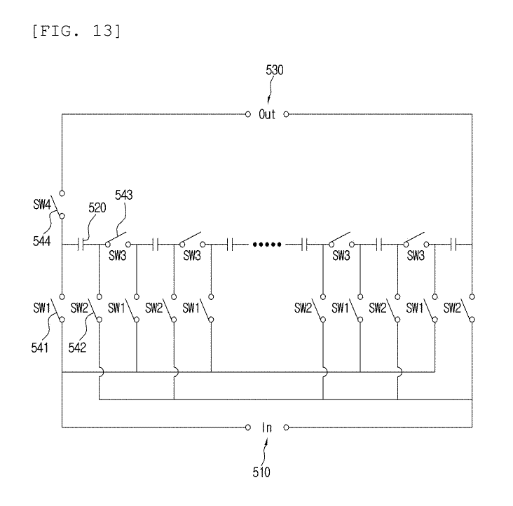

FIG. 14 is a circuit diagram illustrating that electric energy is applied to a plurality of capacitors according to an exemplary embodiment of the present disclosure.

As illustrated in FIG. 14, at least one capacitor 520 which is connected to the turned-on input switch set is connected to the voltage input unit 510 in parallel and is charged with the voltage applied from the voltage input unit 510. The plurality of third switches 543 and the fourth switch 544 are turned off so that no current flows into the voltage output unit 530.

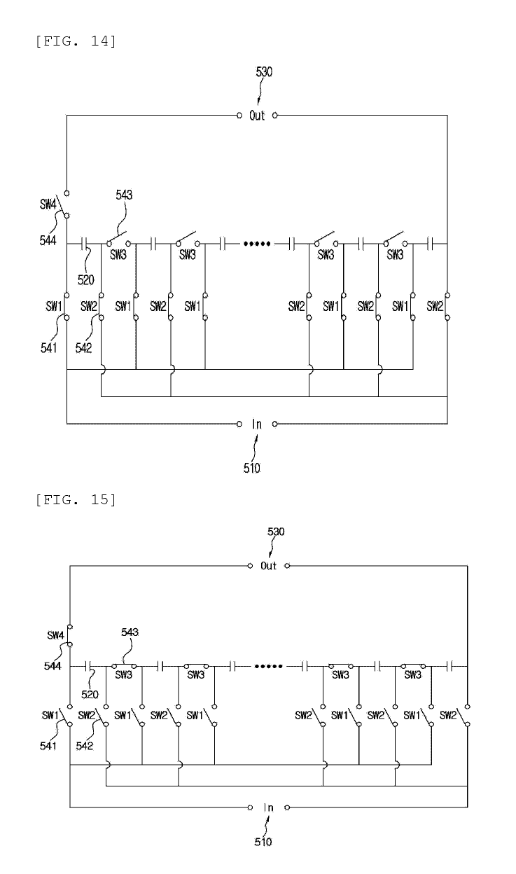

FIG. 15 is a circuit diagram illustrating that the electric energy, which is applied to a plurality of capacitors according to an exemplary embodiment of the present disclosure, is applied to a voltage output unit.

As illustrated in FIG. 15, the plurality of input switch sets is turned off and the plurality of third switches 543 and the fourth switch 544 are turned on to control the voltage applied to the plurality of capacitors 520 to be applied to the voltage output unit 530.

That is, the charged capacitors 520 are connected in series so that a total voltage of the capacitors 520 may be a sum of voltages, which are charged in each capacitor 520. Therefore, the voltage, which is output from the thermoelectric charging apparatus, is boosted up.

In the meantime, when the voltage generated in the thermoelectric charging apparatus is sufficient, there is no need to charge all the plurality of capacitors 520.

For example, when the voltage boosting module 500 includes ten capacitors 520, a voltage generated in the thermoelectric charging apparatus is 0.45 V, and a voltage required for charging is 4.5 V, if all of the ten capacitors 520 are charged and connected in series, the voltage may be boosted from 0.45 V to 4.5 V.

The present disclosure can be implemented as a computer-readable code in a computer-readable recording medium. The computer readable recording medium includes all types of recording device in which data readable by a computer system is stored. Examples of the computer readable recording medium are a ROM, a RAM, a CD-ROM, a magnetic tape, a floppy disk, an optical data storing device and also implemented as a carrier wave (for example, transmission through the Internet). Further, the computer readable recording medium is distributed in computer systems connected through a network and a computer readable code is stored therein and executed in a distributed manner. Further, a functional program, a code, and a code segment, which may implement the present disclosure, may be easily deducted by a programmer in the art.

In the portable thermoelectric charging apparatus and a manufacturing method thereof described above, the configuration and method of embodiments as described above may not be applied with limitation, but the embodiments may be configured by selectively combining all or a part of each embodiment such that various modifications may be made.

The present disclosure to which the above-described configuration is applied may provide a charging apparatus, which is capable of charging portable electronic equipment while being easily carried by the user, like the name card.

When the thermoelectric charging apparatus is used, the hot contact which is a point where the first thermoelectric member and the second thermoelectric member are in contact with each other is in contact with a low level of heat source such as a body heat of the human, liquid including hot water or soup, or a hot water pipe for domestic use to cause the temperature difference from a cold contact which is another point where the first thermoelectric member and the second thermoelectric member are in contact with each other, thereby supplying the power.

Further, the electrode change-over switch is used to change the hot contact into the cold contact to be in contact with a cold material such as ice water and the other point is wrapped by a heat insulating material such as a cloth, a tissue, a Styrofoam or an air cap to cause temperature difference, thereby supplying the power.

As described above, the present disclosure is not limited to the exemplary embodiment described above. The present disclosure may be embodied in a modified form which is obvious to those skilled in the art without departing from the technical spirit of the present disclosure claimed in the following claims. The modified embodiment falls within the scope of the present disclosure.

What is claimed is:

1. A flexible thin multi-layered thermoelectric energy generating module which is a thermoelectric energy generating device in which a multi-layered unit thermoelectric sheet is formed, a p-type semiconductor element and an n-type semiconductor element are formed in the unit thermoelectric sheet, and the p-type semiconductor element and the n-type semiconductor element are coupled in the same horizontal and vertical direction, respectively, to form a p/n semiconductor with an electric parallel circuit configuration,
wherein in the unit thermoelectric sheet, a thermoelectric semiconductor unit in which a plurality of p-type semiconductor elements and a plurality of n-type semiconductor elements are alternately formed, a contact unit in which the thermoelectric semiconductor unit forms an electric contact to generate thermoelectric phenomenon, and an electrode unit which is connected to the thermoelectric semiconductor unit to move electric energy formed in the contact unit and converted into a positive electrode and a negative electrode to transfer the energy to the outside are formed.

2. The flexible thin multi-layered thermoelectric energy generating module according to claim 1, wherein a via hole is formed in the electrode unit to be configured in the positive electrode and the negative electrode with the same shape.

3. The flexible thin multi-layered thermoelectric energy generating module according to claim 1, wherein the electrode unit is formed on a top layer of the unit thermoelectric sheet.

4. A flexible thin multi-layered thermoelectric energy generating module which is a thermoelectric energy generating device in which a multi-layered unit thermoelectric sheet is formed, a p-type semiconductor element and an n-type semiconductor element are formed in the unit thermoelectric sheet, and the p-type semiconductor element and the n-type semiconductor element intersect in horizontal and vertical directions, respectively, to form a p/n semiconductor with an electric series circuit configuration,
wherein in the unit thermoelectric sheet, a thermoelectric semiconductor unit in which a plurality of p-type semiconductor elements and a plurality of n-type semiconductor elements are alternately formed, a contact unit in which the thermoelectric semiconductor unit forms an electric contact to generate thermoelectric phenomenon, and an electrode unit which is connected to the thermoelectric semiconductor unit to move electric energy formed in the contact unit and converted into a positive electrode and a negative electrode to transfer the energy to the outside are formed.

5. The flexible thin multi-layered thermoelectric energy generating module according to claim 4, wherein on each layer of the unit thermoelectric sheet, via holes are alternately formed in a positive electrode and a negative electrode.

6. The flexible thin multi-layered thermoelectric energy generating module according to claim 4, wherein any one of the positive electrode and the negative electrode of the electrode unit is formed on a top layer or a bottom layer of the unit thermoelectric sheet.

7. The flexible thin multi-layered thermoelectric energy generating module according to any one of claims 1 to 4, wherein the unit thermoelectric sheet is formed by a polymer based substrate which is flexible and curved, such as a polyimide film or a PDMS film.

8. The flexible thin multi-layered thermoelectric energy generating module according to any one of claims 1 to 4, wherein the contact units are stepwisely formed as a laminated structure to be coupled to each other.

9. A voltage boosting module which boosts an output voltage of a thermoelectric charging apparatus, the voltage boosting module comprising:
a voltage input unit which receives an output voltage of the thermoelectric charging apparatus;
a plurality of capacitors which is connected to the voltage input unit in parallel and is connected to each other in series;
a voltage output unit which is connected to both ends of the plurality of capacitors connected in series to output a voltage which is applied to the plurality of capacitors;
a plurality of input switch sets including a first switch which controls a current between one end of each of the plurality of capacitors and one end of the voltage input unit and a second switch which controls a current between the other end of each of the plurality of capacitors and the other end of the voltage input unit;
a plurality of third switches which controls a current between a node to which the first switch is connected and a node to which the second switch is connected between the plurality of capacitors;
a fourth switch which controls the current between the node to which the first switch is connected and one end of the voltage output unit, between both ends of the plurality of capacitors; and
a control unit which controls operations of the plurality of input switch sets, the plurality of third switches, and the fourth switch,
wherein the control unit turns on at least one of the plurality of input switch sets and turns off the plurality of third switches and the fourth switch to control an output voltage of the thermoelectric charging apparatus to be applied to at least one of the plurality of capacitors, and turns off the plurality of input switch sets and turns on the plurality of third switches and the fourth switch to control a voltage which is applied to the plurality of capacitors to be applied to the voltage output unit.

10. The voltage boosting module according to claim 9, further comprising:
a power measuring sensor which measures electric power applied to the plurality of capacitors; and
a display unit which outputs the electric power.

11. A thermoelectric charging apparatus, comprising:
a thermoelectric energy generating module which converts thermal energy into electric energy;
a voltage boosting module which is electrically connected to the thermoelectric energy generating module to boost a voltage of the electric energy;
an output unit which is electrically connected to the voltage boosting module to output the electric energy whose voltage is boosted by the voltage boosting module; and
a control unit,
wherein the thermoelectric energy generating module includes a first substrate on which a plurality of first thermoelectric members is deposited and a second substrate on which a plurality of second thermoelectric members is deposited, the first thermoelectric members and the second thermoelectric members form thermocouples, the first substrate and the second substrate are welded such that a surface on which the plurality of first thermoelectric members is deposited and a surface on which the plurality of second thermoelectric members is deposited are in contact with each other, the plurality of first thermoelectric members is deposited in a direction from one end of the first substrate toward the other end and the plurality of second thermoelectric members is deposited in a direction from one end of the second substrate toward the other end, the plurality of first thermoelectric members and the plurality of second thermoelectric members are alternately connected in series and one end of an n-th thermoelectric member of the plurality of first thermoelectric members and the other end of an n+1-th thermoelectric member are connected by the second thermoelectric member,
the voltage boosting module is electrically connected to one end and the other end of the first thermoelectric member and the second thermoelectric member which are connected in series and the first substrate and the second substrate are flexible substrates,
the voltage boosting module includes
a voltage input unit which receives the electric energy;
a plurality of capacitors which is connected to the voltage input unit in parallel and is connected to each other in series;
a voltage output unit which is connected to both ends of the plurality of capacitors connected in series to output electric energy with a voltage, which is applied to the plurality of capacitors, to the output unit;
a plurality of input switch sets including a first switch which controls a current between one end of each of the plurality of capacitors and one end of the voltage input unit and a second switch which controls a current between the other end of each of the plurality of capacitors and the other end of the voltage input unit;
a plurality of third switches which controls a current between a node to which the first switch is connected and a node to which the second switch is connected between the plurality of capacitors; and
a fourth switch which controls the current between the node to which the first switch is connected between both ends of the plurality of capacitors and one end of the voltage output unit; and
the control unit turns on at least one of the plurality of input switch sets and turns off the plurality of third switches and the fourth switch to control an output voltage of the thermoelectric energy generating module to be applied to at least one of the plurality of capacitors, and turns off the plurality of input switch sets and turns on the plurality of third switches and the fourth switch to control a voltage which is applied to the plurality of capacitors to be applied to the voltage output unit.

12. The thermoelectric charging apparatus according to claim 11, further comprising:
an electrode change-over switch which changes a polarity of the electric energy output from the output unit into an opposite polarity.

13. The thermoelectric charging apparatus according to claim 11, further comprising:
a storage battery which is electrically connected to the voltage boosting module to store the electric energy,
wherein the output unit is electrically connected to the storage battery to output the stored electric energy.

14. The thermoelectric charging apparatus according to claim 11, wherein the voltage of the electric energy, which is converted by the thermoelectric energy generating module is determined by the following Equation.
E(V)=(T₁−T₂)×S×n [Equation]
(in Equation, E(V) is a voltage of the electric energy, T₁ is a temperature at a point where one end of the plurality of first thermoelectric members and one end of the plurality of second thermoelectric members are in contact with each other, T₂ is a temperature at a point where the other end of the plurality of first thermoelectric members and the other end of the plurality of second thermoelectric members are in contact with each other, S is a Seebeck coefficient of the thermocouple formed by the first thermoelectric member and the second thermoelectric member, and n is the number of thermocouples formed by the plurality of first and second thermoelectric members.)

15. The thermoelectric charging apparatus according to claim 11, further comprising:
a power measuring sensor which measures electric power applied to the plurality of capacitors; and
a display unit which outputs the electric power.
